(19) United States
(12) Patent Application Publication
(10) Pub. No.: US 2010/0032191 A1
(43) Pub. Date: Feb. 11, 2010

(54) FLEXIBLE PRINTED CIRCUITBOARD STRUCTURE

(75) Inventors: Chin-Wen LO, Taichung City (TW); Chia-Ning KAO, Taichung City (TW); Chin-Mei HUANG, Taichung City (TW)

Correspondence Address: WPAT, PC;INTELLECTUAL PROPERTY ATTORNEYS, 7225 BEVERLY ST., ANNANDALE, VA, 22003, US

(73) Assignee: WINTEK CORPORATION, Taichung (TW)

(21) Appl. No.: 12/535,085

(22) Filed: Aug. 4, 2009

(30) Foreign Application Priority Data
Aug. 5, 2008 (TW) 097129691

(51) Int. Cl. H05K 1/00

(52) U.S. Cl. 174/254

(57) ABSTRACT

A flexible printed circuitboard structure is disclosed, which comprises: a flexible printed circuitboard (FPC), having at least a soldering pad and at least a solder pasted pad area formed thereon; wherein, by using the extending of a side of the at least one solder pasted pad area as the base line, a bending line is formed on the FPC in a manner that it is prevented from passing through the at least one soldering pad and is disposed at a specific distance away from the periphery of the same. By the configuration of the solder pasted pad area to defined the bending line on the FPC, the bending stress problems caused when the FPC is being bended, such as solder crack and broken circuit, etc., can be prevented.

### FIELD OF THE INVENTION

The present invention relates to an anti-solder crack structure for flexible printed circuitboard (FPC), and more particularly, to an anti-solder crack structure capable of defining its bending stress to be concentrated at a specific position on a FPC as the FPC is being bended by a solder pasted pad layout and thus preventing the bending stress problems such as solder crack and broken circuit, etc., from happening.

### BACKGROUND OF THE INVENTION

At the era of thinner, lighter and smaller, the role of those rigid print circuit boards in the consumer electronic products is gradually being replaced by flexible printed circuitboard (FPC) as it is flexible, light-weighted and thin. However, the layout of the FPC is not that different from that of the rigid print circuit board. Please refer to FIG. 1, which shows a conventional flexible printed circuitboard. In FIG. 1, the FPC 10 is substantially a flexible board 10 having a plurality of soldering pads 20a˜20d formed thereon; and those soldering pads 20a˜20d can be formed in different shapes. As the top edges 11, 12 of the flexible board 10 is designed to be fixed, the flexible board 10 is likely to be bended laterally. Thus, when the flexible board 10 is bended by an external force, the stresses resulting from the bending will concentrate around the soldering pads 20a˜20d since the hardness of the soldering pads 20a˜20d is quite different from that of the flexible board 10. Therefore, bending lines L1a˜L1e, that some may extend laterally while some may extend by an inclined angle as those shown in FIG. 1, are formed on the flexible board 10 by the concentration of the bending stress in a manner that some of the soldering pads 20a˜20d may be cracked and thus separated from the flexible board 10.

In the flexible printed circuitboard shown in FIG. 2, the soldering pads are formed in pairs on the flexible board 10A of the FPC, which is exemplified by the pair of soldering pads 21, 22. In FIG. 2, the pair of soldering pads 21, 22 is provided for mounting an electronic component 30 thereon and is connected by a routing 40 also formed on the flexible board 10A. Similarly, when the flexible board 10A is bended by an external force, the stresses resulting from the bending will concentrate around the soldering pads 21, 22 which cause the formation of two bending lines L21, L22. Nevertheless, since the electronic component 30 is mounted on the pair of soldering pads 21, 22 that provides a certain strength to the area defined between the two soldering pads 21, 22, the bending stress is in some way being prevented from concentrating in the area defined between the two soldering pads 21, 22. However, as the bending lines L21, L22 are still being formed right along the outer sides of the two soldering pads 21, 22, the soldering pads 21, 21 may still be cracked by the bending stress and thus separated from the flexible board 10A which cause broken circuit to the electronic component 30 as it is electrically disconnected with the routing 40.

### SUMMARY OF THE INVENTION

In view of the disadvantages of prior art, the primary object of the present invention is to provide a flexible printed circuitboard structure which is capable of preventing the bending stress problems such as solder crack and broken circuit, etc., from happening by changing the position on the FPC where the bending stress is concentrated.

To achieve the above object, the present invention provides flexible printed circuitboard structure, comprising: a flexible printed circuitboard (FPC), having at least a soldering pad and at least a solder pasted pad area formed thereon; wherein, by using the extending of a side of the at least one solder pasted pad area as the base line, a bending line is formed on the FPC in a manner that it is prevented from passing through the at least one soldering pad and is disposed at a specific distance away from the periphery of the same.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 and FIG. 2 show two conventional flexible printed circuitboards.

FIG. 3 shows a flexible printed circuitboard structure according to an exemplary embodiment of the invention.

FIG. 4 shows a flexible printed circuitboard structure according to another exemplary embodiment of the invention.

FIG. 5 to FIG. 8 respectively shows different solder pasted pad areas being formed on the FPC of FIG. 4.

FIG. 9 and FIG. 10 respectively shows different solder pasted pad areas being formed on a FPC that is different from the one shown in FIG. 4.

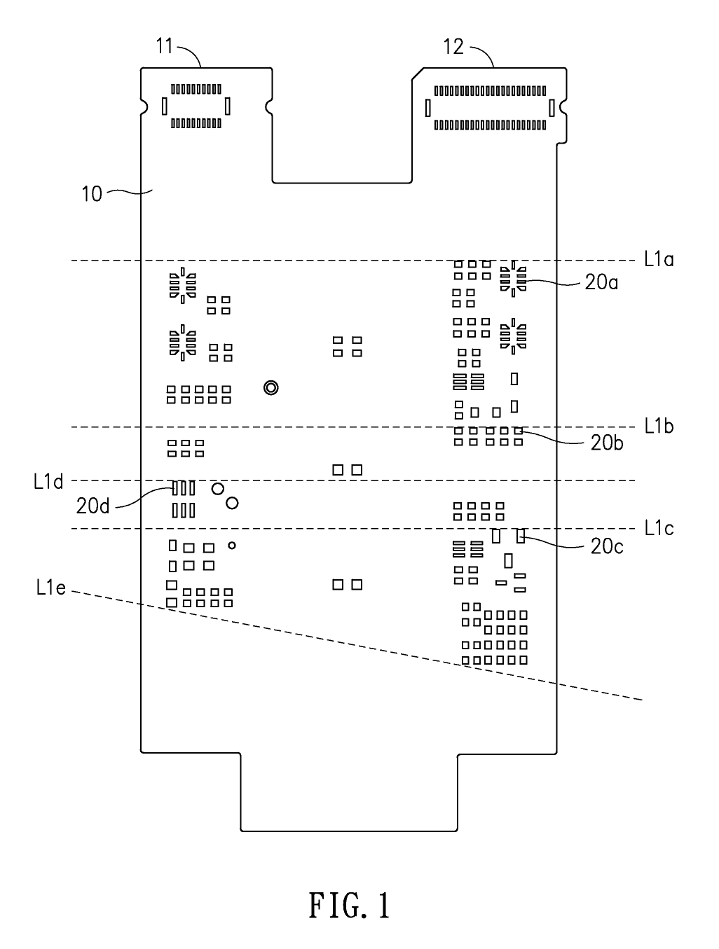

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

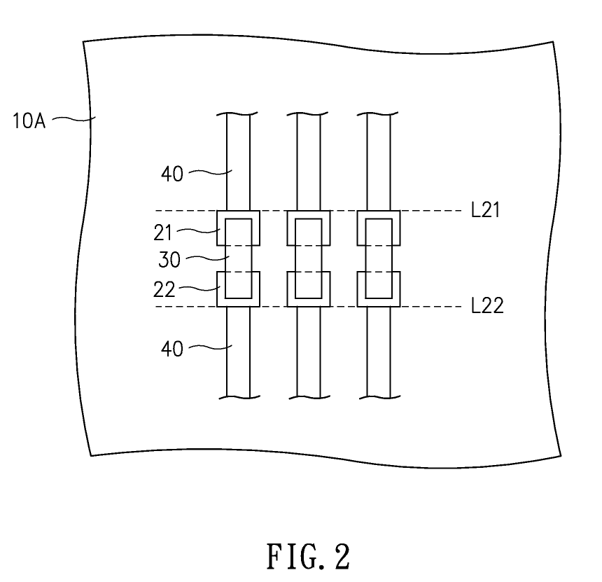

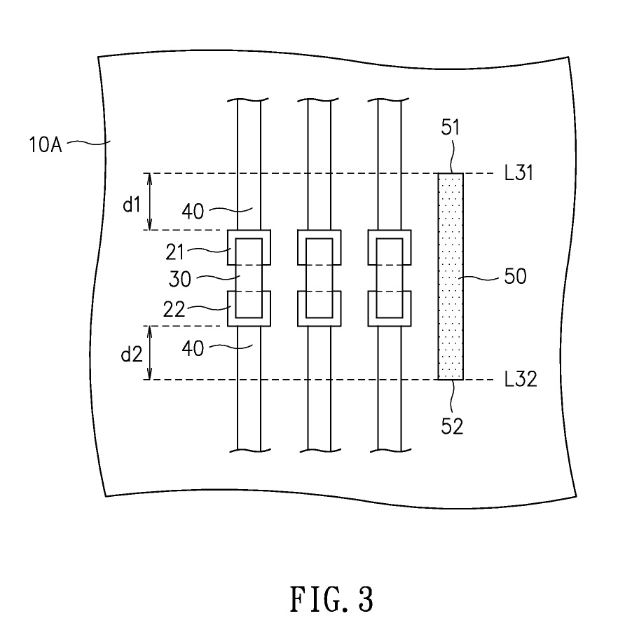

Please refer to FIG. 3, which shows a flexible printed circuitboard structure according to an exemplary embodiment of the invention. In FIG. 3, there are a plurality of soldering pads formed in pairs on the flexible board 10A, which is exemplified by the pair of soldering pads 21, 22. In FIG. 2, the pair of soldering pads 21, 22 is provided for mounting an electronic component 30 thereon and is connected by a routing 40 also formed on the flexible board 10A. In addition, there is at least a solder pasted pad area 50 being formed on the FPC 10A that by using the extending of one side 51 of the solder pasted pad area 50 as the base line for bending the FPC 10A, a bending line L31 is formed on the FPC 10A in a manner that it is prevented from passing through the soldering pad 21 and is disposed at a specific distance d1 away from the periphery of the same. Similarly, by using the extending of another side 52 of the solder pasted pad area 50 as the base line for bending the FPC 10A, another bending line L32 is formed on the FPC in a manner that it is prevented from passing through the soldering pad 22 and is disposed at a specific distance d2 away from the periphery of the same. As the two bending lines L31, L32 are formed by the formation of the solder pasted pad area 50 for preventing the same from passing through the soldering pads 21, 22 and being disposed away from the same by the distances d1, d2 in respective, the stress generated by the bending of the FPC 10A that were to be concentrated just around the periphery of the two soldering pads 21, 22, is now being shifted to concentrate at positions relating to the two bending lines L31, L32. Thereby, the two soldering pads 21, 22 can be free from the danger of cracking by the bending stress. It is noted that the distances d1 and d2 can be any value that is determined basing upon the actual size of the FPC 10A, as well as the layout of the soldering pads 21, 22 and the routing 40. In addition, although the bending lines L31 and L32 will intersect with the routing 40, it will not cause the routing 40 to break, not only because that the routing 40 is sandwiched inside the FPC 10A, but also because it is very thin.

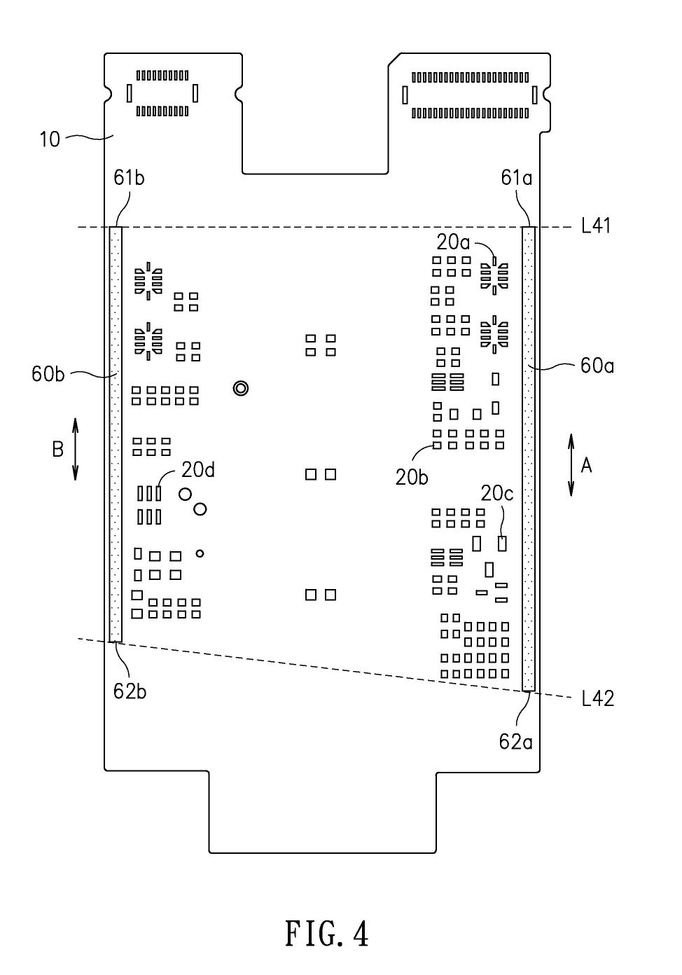

Please refer to FIG. 4, which shows a flexible printed circuitboard structure according to another exemplary embodiment of the invention. Generally, there can be many soldering pads 20a˜20e being formed on a FPC 10, in that the shape of different soldering pad can be different. Following the same design principle as the embodiment shown in FIG. 3, the FPC 10 has a first solder pasted pad area 60a and a second solder pasted pad area 60b formed thereon at positions outside the soldering pads 20a˜20e and close to the edge of the FPC 10 in a manner that all the soldering pads 20a˜20e are sandwiched between the first and the second sold pasted pad areas 60a and 60b, Therefore, when the FPC 10 is being bended, the soldering pads 20a˜20e can be prevented from being affected by the resulting bending stress as they are protected by the blocking of the two solder pasted pad areas 60a and 60b. As shown in FIG. 4, by using the extending of a side 61a of the first solder pasted pad area 60a as the base line for bending the FPC 10, a first bending line L41 is formed on the FPC 10 and is formed passing through a side 61b of the second solder pasted pad area 60b. Similarly, by using the extending of another side 62a of the first solder pasted pad area 60a as the base line for bending the FPC 10, a second bending line L42 is formed on the FPC 10 and is formed passing through another side 62b of the second solder pasted pad area 60b. Therefore, a polygon zone can be defined within the first solder pasted pad area 60a, the second solder pasted pad area 60b, the first bending line L41 and the second bending line L42 in a manner that all the soldering pads 20a˜20e formed on the FPC 10 are disposed inside the polygon zone. When the FPC 10 is bended, all the soldering pads 20a˜20e are free from the danger of cracking by the bending stress since the first and the second bending lines L41, L42 are formed at positions outside the area where those soldering pads 20a˜20e are disposed. It is noted that there is no restriction relating to the layout of the two solder pasted pad areas 60a and 60b as well as their positions, lengths and shapes, they can be determined basing upon the actual size of the FPC 10, the space available on the FPC 10, the amount of soldering pads disposed on the FPC 10 as well as the positioning of the soldering pads. In this exemplary embodiment, the first solder pasted pad area 60a and the second solder pasted pad area 60b are shaped like bar-like rectangles of different lengths, while the extending along the length of the first solder pasted pad area 60a is parallel with that of the second solder pasted pad area 60b.

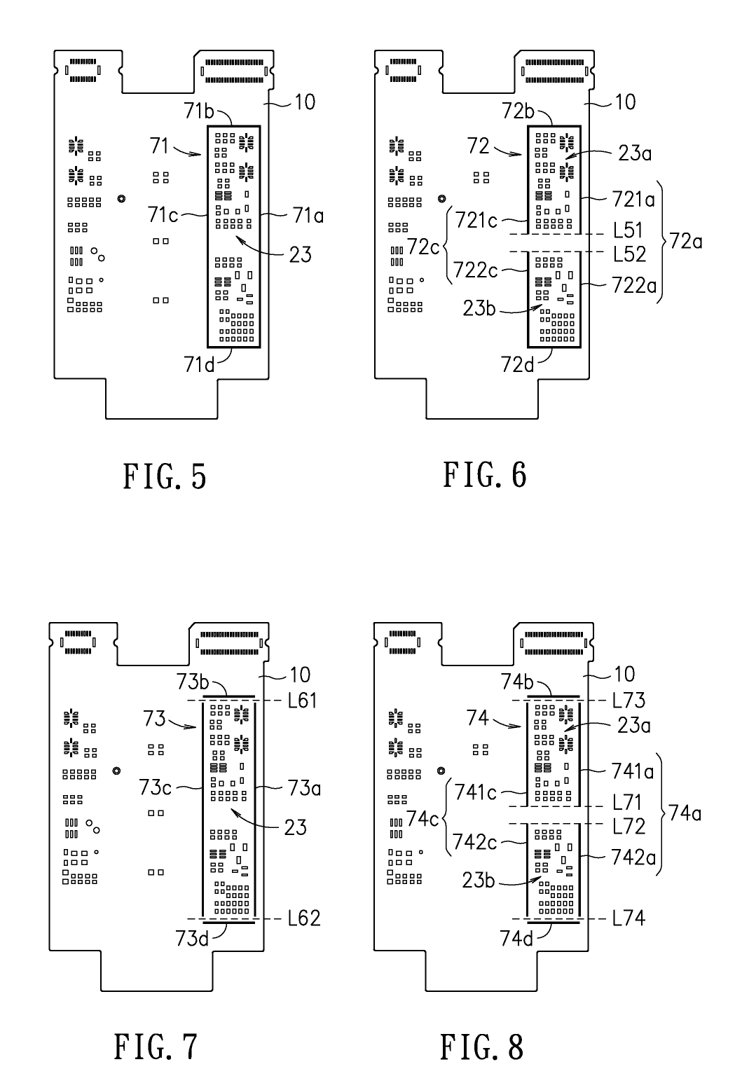

In the embodiment shown in FIG. 5, there are four solder pasted pad areas 71a, 71b, 71c and 71d being formed on the FPC 10 in a manner that the four solder pasted pad areas 71a, 71b, 71c and 71d are connected with each other while together enclose a polygon zone 71 so as to enable all the soldering pads 23 to be disposed inside the polygon zone 71. Thereby, while the FPC 10 is bended by an external force, there will be no bending line being formed in the polygon zone 71 so that the soldering pads 23 inside the same are protected from cracking by the bending stress.

In the embodiment shown in FIG. 6, there are four solder pasted pad areas 72a, 72b, 72c and 72d being formed on the FPC 10 in a manner that the four solder pasted pad areas 72a, 72b, 72c and 72d are connected with each other while together enclose a polygon zone 72 so as to enable all the soldering pads 23 to be disposed inside the polygon zone 72. Nevertheless, the aforesaid embodiment is characterized in that: the two solder pasted pad areas 72a and 72c are cut off and thus being divided into discontinuous sections 721a, 722a and 721c, 722c in respective so that upper portion of the soldering pads 23a is protected by the upper sections 721a, 721c of the two solder pasted pad areas 72a and 72c and the solder pasted pad area 72b, while the lower portion of the soldering pads 23b is protected by the lower sections 722a, 722c of the two solder pasted pad areas 72a and 72c and the solder pasted pad area 72d. Thereby, while the FPC 10 is bended by an external force, the soldering pads 23a and 23b can still be protected from cracking by the bending stress despite that there are two bending lines L51 and L52 being formed right at positions where the two solder pasted pad areas 72a and 72c are cut off since the extending of the two bending lines L51 and L52 is no where near the soldering pads 23a, 23b.

In the embodiment shown in FIG. 7, there are four solder pasted pad areas 73a, 73b, 73c and 73d being formed on the FPC 10 in a manner that the four solder pasted pad areas 73a, 73b, 73c and 73d are not connected with each other while together enclose a polygon zone 73 so as to enable all the soldering pads 23 to be disposed inside the polygon zone 71. Thereby, while the FPC 10 is bended by an external force, the soldering pads 23 can still be protected from cracking by the bending stress despite that there are two bending lines L61 and L62 being formed respectively at the discontinuity between the solder pasted pad areas 73a, 73c and 73b, as well as that of the solder pasted pad areas 73a, 73c and 73d since the extending of the two bending lines L61 and L62 is no where near the soldering pads 23.

In the embodiment shown in FIG. 8, there are four solder pasted pad areas 74a, 74b, 74c and 74d being formed on the FPC 10 in a manner that the four solder pasted pad areas 74a, 74b, 74c and 74d are not connected with each other while together enclose a polygon zone 74 so as to enable all the soldering pads 23a and 23b to be disposed inside the polygon zone 74. Nevertheless, the aforesaid embodiment is characterized in that: the two solder pasted pad areas 74a and 74c are cut off and thus being divided into discontinuous sections 741a, 742a and 741c, 742c in respective so that upper portion of the soldering pads 23a is protected by the upper sections 741a, 741c of the two solder pasted pad areas 74a and 74c and the solder pasted pad area 74b, while the lower portion of the soldering pads 23b is protected by the lower sections 742a, 742c of the two solder pasted pad areas 74a and 74c and the solder pasted pad area 74d. Thereby, while the FPC 10 is bended by an external force, the soldering pads 23a and 23b can still be protected from cracking by the bending stress despite that there are two bending lines L71 and L72 being formed right at positions where the two solder pasted pad areas 74a and 74c are cut off, and there are another two bending lines L73 and L74 being formed respectively at the discontinuity between the solder pasted pad areas 74a, 74c and 74b, as well as that of the solder pasted pad areas 74a, 74c and 74d since the extending of the bending lines L71, L72, L73 and L74a are no where near the soldering pads 23a, 23b.

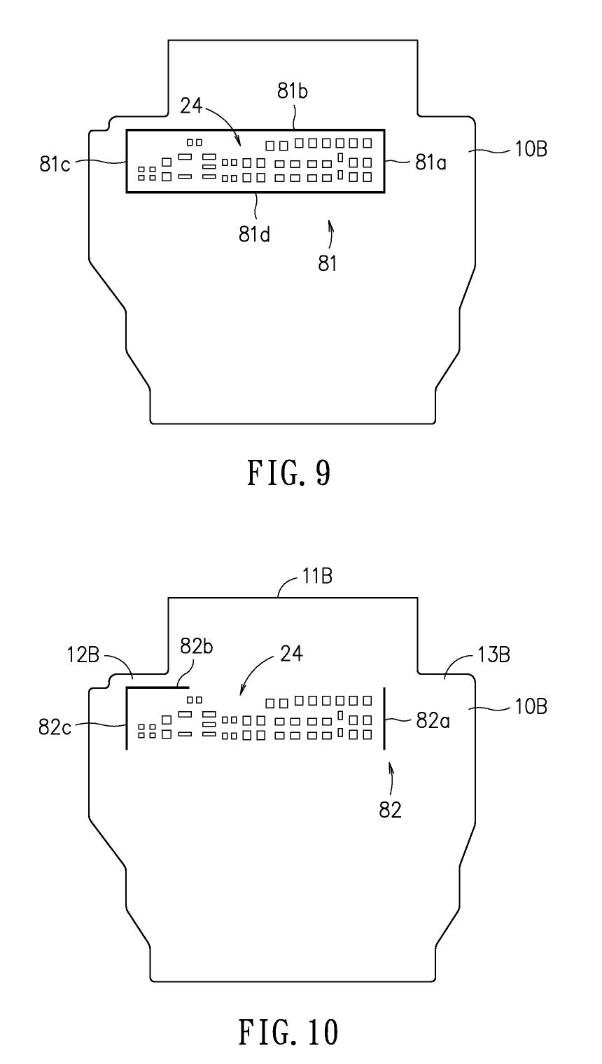

In the embodiment shown in FIG. 9, the flexible board 10B of the printed circuitboard structure is formed with a shape different from that shown in FIG. 8, whereas the flexible board 10B is configured with four solder pasted pad areas 81a, 81b, 81c and 81d, being connected with each other for enclosing a polygon zone 81 therein and thus enabling all the soldering pads 24 to be disposed inside the polygon zone 81. Thereby, while the FPC 10B is bended by an external force, there will be no bending line being formed in the polygon zone 81 so that the soldering pads 24 inside the same are protected from cracking by the bending stress. From the above description relating to the embodiment shown in FIG. 9, it is noted that the disposition of the solder pasted pad areas is dependent upon the layout of the soldering pads on the flexible board. Although the polygon zone 81 is formed on the flexible board 10B in a transverse-extending manner which is different from the polygon zone 71 shown in FIG. 5 as it is extending along the longitudinal direction of the board 10, the two polygon zones 71, 81 are actually designed for achieving the same effect.

In the embodiment shown in FIG. 10, there are three solder pasted pad areas 82a, 82b, and 82c being formed on the flexible board 10B, in which the two solder pasted pad areas 82a, 82c are disposed parallel with each other while the solder pasted pad areas 82b is disposed perpendicular to the solder pasted pad areas 82c while connecting to the same. In this embodiment, as the top edges 11B of the flexible board 10B is designed to be fixed, the flexible board 10B is likely to be bended laterally. Thus, for protecting the soldering pads from cracking by bending stress, it is important to prevent the bending lines form forming in a transverse-extending manner on the flexible board 10B. In this embodiment, the two parallel solder pasted pad areas 82a, 82c are formed on the flexible board 10B for preventing the formation of transverse-extending bending lines from intersecting with any soldering pads 24 which are acting the same as the first and the second solder pasted pad areas 60a, 60b shown in FIG. 4. In addition, as the flexible board 10B is configured with a protruding shoulder portion 12B while there are a portion of the soldering pads 24 being disposed on the protruding shoulder portion 12B, the solder pasted pad area 82b are formed on the protruding shoulder portion 12B in a manner that it is perpendicular to the solder pasted pad area 82c while connecting to the same so as to protect those the portion of the soldering pads 24 disposed on the protruding shoulder portion 12B from cracking as the protruding shoulder portion 12B is likely to be bended along the longitudinal direction of the same. On the other hand, although there is another protruding shoulder portion 13B formed on the flexible board 10B at position opposite to the shoulder portion 12B, there is no soldering pad formed on that protruding shoulder portion 13B so that no solder pasted pad area is required.

To sum up, the present invention provides an improved flexible printed circuitboard structure which is capable of preventing the bending stress problems such as solder crack and broken circuit, etc., from happening by forming solder pasted pad areas on a FPC for changing the position on the FPC where the bending stress is concentrated. In addition, the shapes as well as the layouts of those solder pasted pad areas are dependent upon the layout of the FPC as well as the soldering pads. It is noted that the forming of any solder pasted pad areas on the FPC is for changing the position on the FPC where the bending stress is concentrated and thus enabling the bending lines to be formed on the FPC at locations away from its soldering pads.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A flexible printed circuitboard structure, comprising:
a flexible printed circuitboard (FPC), having at least a soldering pad formed thereon; and
at least a solder pasted pad area, formed on the FPC;
wherein, by using the extending of at least a side of the at least one solder pasted pad area as the base line for bending the FPC, a bending line is formed on the FPC in a manner that it is prevented from passing through the at least one soldering pad and is disposed at a specific distance away from the periphery of the same.

2. The flexible printed circuitboard structure of claim 1, wherein the FPC has a first solder pasted pad area and a second solder pasted pad area formed thereon in a manner that by using the extending of a side of the first solder pasted pad area as the base line for bending the FPC, a first bending line is formed on the FPC and is formed passing through a side of the second solder pasted pad area.

3. The flexible printed circuitboard structure of claim 2, wherein by using the extending of another side of the first solder pasted pad area as the base line for bending the FPC, a second bending line is formed on the FPC and is formed passing through another side of the second solder pasted pad area.

4. The flexible printed circuitboard structure of claim 3, wherein a polygon zone is defined within the first solder pasted pad area, the second solder pasted pad area, the first bending line and the second bending line in a manner that the at least one soldering pad is disposed inside the polygon zone.

5. The flexible printed circuitboard structure of claim 4, wherein the polygon zone is shaped like a quadrangle.

6. The flexible printed circuitboard structure of claim 3, wherein the first solder pasted pad area and the second solder pasted pad area are each shaped like a bar-like rectangle with a specific length.

7. The flexible printed circuitboard structure of claim 6, wherein the extending along the length of the first solder pasted pad area is parallel with that of the second solder pasted pad area.

8. The flexible printed circuitboard structure of claim 6, wherein the length of the first solder pasted pad area is different from that of the second solder pasted pad area.

9. The flexible printed circuitboard structure of claim 1, wherein there are a plurality of solder pasted pad areas being formed on the FPC in a manner that the plural solder pasted pad areas are connected with each other while together enclose a polygon zone so as to enable the at least one soldering pad to be disposed inside the polygon zone.

10. The flexible printed circuitboard structure of claim 1, wherein there are a plurality of solder pasted pad areas being formed on the FPC in a manner that the plural solder pasted pad areas are not connected with each other while together enclose a polygon zone so as to enable the at least one soldering pad to be disposed inside the polygon zone.

11. The flexible printed circuitboard structure of claim 1, wherein there are a plurality of solder pasted pad areas being formed on the FPC in a manner that at least two of the plural solder pasted pad areas are connected with each other while together enclose a polygon zone so as to enable the at least one soldering pad to be disposed inside the polygon zone.

12. The flexible printed circuitboard structure of claim 1, wherein there are a plurality of soldering pads formed on the FPC in groups in a manner that the bending line formed on the FPC is prevented from passing through any of the groups and is disposed at a specific distance away from the periphery of the same as each group of soldering pads is provided for mounting an electronic component.
